(19) United States
(12) Patent Application Publication
(10) Pub. No.: US 2008/0043798 A1
(43) Pub. Date: Feb. 21, 2008

(54) Vertical-Cavity Semiconductor Optical Devices

(75) Inventors: Stephane Luc Dominique Calvez, Glasgow (GB); John-Mark Hopkins, Glasgow (GB); David Burns, Glasgow (GB); Martin David Dawson, Bridge of Weir (GB); Chan Wook Jeon, Seoul (KR); Hoi Wai Choi, Hong Kong (CN)

Correspondence Address: STOUT, UXA, BUYAN & MULLINS LLP, 4 VENTURE, SUITE 300, IRVINE, CA, 92618, US

(73) Assignee: The University of Strathclyde, Glasgow (GB)

(21) Appl. No.: 10/550,846

(22) PCT Filed: Mar. 24, 2004
(86) PCT No.: PCT/GB04/01285

§ 371 Date: Apr. 17, 2007

(30) Foreign Application Priority Data
Mar. 24, 2003 (GB) 0306800.4

(51) Int. Cl. H01S 5/026

(52) U.S. Cl. 372/50.22

(57) ABSTRACT

A vertical-cavity device comprises: (a) a chip comprising an active semiconductor layer for providing optical gain; (b) a first mirror arranged on a first side of the active layer; (c) a second mirror arranged on a second side of the active layer, opposite to the first mirror, and forming with at least the first mirror an optically resonant cavity that passes through the active layer in a direction out of the plane of the active layer; (d) a heatspreader for removing heat from the active layer, the heatspreader being arranged inside the cavity and having a first surface adjacent to the chip and a second surface opposite to the first surface, the heatspreader being transparent to light of wavelengths in an operating bandwidth of the device. In addition to removing heat from the active layer, the heatspreader also has one or more further selected property that has a further selected effect on light output from the device.

This invention relates to the field of vertical-cavity semiconductor optical devices, in particular to devices such as Vertical-cavity Surface-emitting Lasers (VCSELs), Vertical extended-cavity Surface-emitting Lasers (VECSELs) and Vertical-cavity Semiconductor Optical Amplifiers (VCSOAs).

Semiconductor lasers are by far the most common form of laser available in the world today. They are in general fabricated by depositing layers of semiconductor on a substrate material.

Pump energy may be supplied electrically or optically to a semiconductor laser to achieve a population inversion in the active region of the laser.

Most semiconductor lasers are Edge-emitting Lasers (EELs). In an EEL, an active region is formed by sandwiching a layer of semiconductor material having a lower bandgap energy between two layers of semiconductor materials having higher bandgap energies. The active region usually has a higher refractive index than the adjacent layers and so emitted light is confined by the index steps to the active layer. An EEL thus emits light in a direction in the plane of the active layer. Mirrors providing feedback for lasing action can be provided by various means, including cleaving the end-faces of the semiconductor wafer forming the laser or providing Bragg gratings in the plane of the active layer.

A disadvantage of EELs is that they produce an output beam that is of relatively poor quality in some respects. The active region, viewed from the edge from which light is emitted is typically much wider than it is high. That asymmetry results in an asymmetric output beam. Although the small height of the active layer usually results in a beam comprising a single transverse mode in the vertical direction, the larger width usually results in many transverse modes in the horizontal direction. This asymmetric non-diffraction-limited output beam can make it difficult to use the diode output beam in many applications. Various ways of overcoming that problem have been implemented but all involve increased complexity of manufacture.

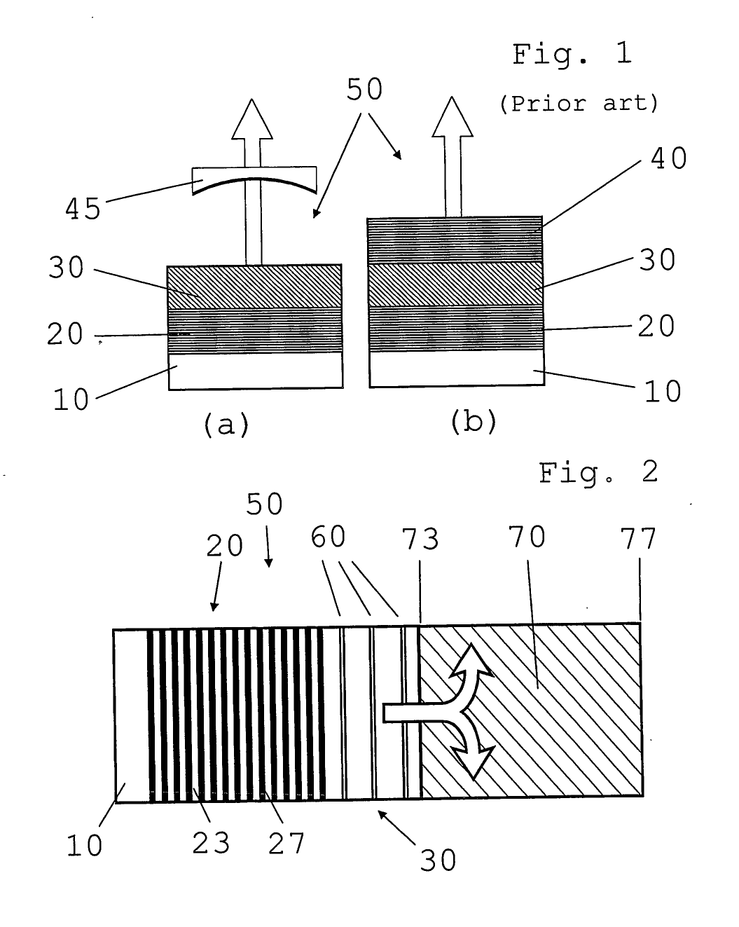

Vertical cavity surface emitting lasers (VCSELs) are semiconductor lasers that, in contrast to EELs, emit light in a direction perpendicular to the plane of the active layer (FIG. 1 (b)). Feedback is provided by mirrors in the form of distributed Bragg reflectors (DBRs) 20, 40, provided above and below active layer 30, formed from alternating in the deposited structure thin layers of material of different refractive indices. The active layer 30 usually includes one or more quantum wells that provide gain. As with EELs, the layers 20, 30, 40 are grown on a wafer substrate 10.

The DBRs 20, 40 consist of alternating quarter wavelength (optical thickness) layers of two or more optically transparent materials with a suitable refractive index contrast to provide a high degree of reflection at the signal (operating) wavelength. When grown monolithically DBR 20 is fabricated from semiconductor material layers on a semiconductor substrate with the subsequent half wavelength (or multiple thereof) laser cavity grown on the upper surface of this mirror 20. This cavity may contain either bulk “gain layers” of active semiconductor or single or multiple thin layers of active semiconductor material (quantum wells) to provide the optical absorption at the pump and device gain at the signal wavelength. These layers are surrounded by an appropriate thickness of “barrier” material to provide carrier confinement, additional pump absorption, and appropriate spacing for the quantum wells for maximum gain enhancement. Maximum gain enhancement is achieved by placing the quantum wells at the oscillating field antinodes for maximum gain extraction efficiency (an arrangement known as resonant periodic gain (RPG).

The gain region may be surrounded by a non-absorbing confinement region to isolate carriers from the device surface and the mirror layers. DBR 40 is then fabricated by deposition of further suitable semiconductor material layers.

This semiconductor chip may be mounted on a suitable temperature-controlled heatsink.

VCSELs provide several advantages over EELs. The very short cavity length (which is approximately the height of the active layer, approximately one-half to fifteen times the wavelength λ of the emitted light, for example typically ˜1 micron) means that a VCSEL operates in a single longitudinal mode, as its mode spacing is greater than the gain bandwidth of the device. Viewed from the direction of emission, the active layer is symmetric, in contrast to an EEL, and so it is much easier to achieve a circular, symmetric output beam. VCSELs typically have low threshold powers for the onset of laser action and they typically have high modulation bandwidths. They are also very stable.

Vertical-cavity devices may be pumped optically or electrically. A disadvantage of electrical pumping is that a relatively complex structure is often necessary in the semiconductor chip in order to optimise delivery of current to the active region. In contrast, optical pumping may be achieved with a semiconductor chip having a relatively simple structure.

However, the output power available from a VCSEL is rather low, typically of the order of 1 mW. Whilst that is adequate in many applications, many more applications become available for a semiconductor laser emitting higher powers. The power available from an electrically pumped VCSEL is limited by the difficulty of maintaining a uniform current distribution and single-transverse-mode operation for large drive-current apertures.

Vertical Extended Cavity Surface Emitting Lasers (VECSELs) are a variation of the VCSEL concept that has been recently developed (M. A. Hadley, et al., “High single-transverse-mode output from external-cavity surface-emitting laser diodes,” Appl. Phys. Lett. 63, 1607-1609 (1993)). In a VECSEL (FIG. 1(a)), one of the DBRs 40 is omitted from the device and feedback is provided instead by one or more optical substrates coated with highly reflective dielectric coatings at the signal wavelength (external mirror 45 in FIG. 1).

Pumping may be electrical or optical, for example in the form of pump light provided by commercial diode lasers of suitable wavelength coupled to the device with suitable optics to provide a tight to moderate focus at the surface of the VECSEL chip. With optical pumping, the VECSEL may act as a mode-converter; a pump diode having a relatively poor, multimode beam may be focused to a relatively tight focus in the active region of the chip, where the beam energy is absorbed and re-emitted in the VECSEL output beam, which is typically a high-quality, single-transverse-mode beam. Although the pump beam is not diffraction limited, and therefore diverges rapidly from a tight focus, the active region of the VECSEL is sufficiently short for that divergence not to be significant within the active region. Thus energy can be efficiently converted from the poor mode of the pump laser to the good mode of the VECSEL.

Use of an external mirror enables production of higher output powers by permitting single mode operation at larger pumping diameters. Continuous wave (CW) powers of over 0.5 W, and pulse peak powers of over 1 W, have been achieved (M. Kuznetsov et al., “High-power (>0.5 W CW) Diode-pumped Vertical-External-Cavity Surface-Emitting Lasers with Circular TEM₀₀ Beams,” IEEE Photonics Tech. Lett. 9, 1063-1065 (1997); S. Hoogland et al., “Passively mode-locked diode-pumped Surface-emitting semiconductor laser”, IEEE Photonics Tech. Lett. 12, 1135-1137 (2000).

The gain provided by a quantum well reduces as temperature increases and the energy distribution of its carriers broadens. The emission wavelength also shifts more quickly to longer wavelengths than the cavity resonance (which shifts due to minor physical thickness and refractive index changes) and will therefore compromise the gain and hence performance of the device when resonant periodic gain (RPG) is used. Removal of heat from the active region is therefore an important design consideration for VECSELs.

W. J. Alford et al. (J. Opt. Soc. Am. B 19, 663 (2002)) describes a VECSEL that provides 1.5 W output power in CW operation and 4.4 W peak power (2 W average power) in pulsed operation. Those high output powers were made possible by the use of a 2-mm thick, 10-mm diameter sapphire window for heat removal. The window was optically contacted to the intracavity surface of the semiconductor, i.e. the surface between the gain region and the external mirror of the VECSEL. The use of a transparent intracavity heatsink is particularly advantageous in a VECSEL because the gain region is close (roughly 0.5 microns) to the intracavity surface of the semiconductor and so heat can be removed far more efficiently from that region than if the heatsink were contacted with the opposite surface of the device, which is separated from the gain region by the DBR and the thick (0.65 mm) wafer substrate.

The Alford device is optically pumped, by a fibre-bundle-coupled diode laser bar. Alford notes that a problem caused by the sapphire window is that not all of the incident pump power is coupled into the semiconductor wafer, due to Fresnel reflections from the air/sapphire and sapphire/wafer interfaces.

Thus use of a transparent intracavity heatsink is known in the prior art.

It should be noted that a laser is of course essentially an optical amplifier that oscillates due to feedback. Power must be supplied to a laser device to create a population inversion, which provides gain. The power for a semiconductor laser is typically supplied optically or electrically. A certain amount of power (the laser threshold power) must be provided for the laser to lase (oscillate) and feedback must be provided. A laser device that does not include feedback (e.g. a VECSEL without a second mirror) or that is not provided with sufficient power for oscillation will act as an amplifier when light of a suitable wavelength is input into the device. Thus a laser device may be operated as a simple or regenerative amplifier, rather than as a laser. A VCSOA is an example of such an amplifier, typically being a VCSEL or VECSEL operated below its lasing threshold.

An object of the invention is to provide an improved vertical-cavity device and a method of fabricating such an improved device.

According to the invention there is provided a vertical-cavity device comprising:
(a) a chip comprising an active semiconductor layer for providing optical gain;
(b) a first mirror arranged on a first side of the active layer;
(c) a second mirror arranged on a second side of the active layer, opposite to the first mirror, and forming with at least the first mirror an optically resonant cavity that passes through the active layer in a direction out of the plane of the active layer;
(d) a heatspreader for removing heat from the active layer, the heatspreader being arranged inside the cavity and having a first surface adjacent to the chip and a second surface opposite to the first surface, the heatspreader being transparent to light of wavelengths in an operating bandwidth of the device;
   characterised in that, in addition to removing heat from the active layer, the heatspreader also has one or more further selected property that has a further selected effect on light output from the device.

As discussed above, it is known in the prior art that wafer bonding of a heatspreader to a semiconductor device drastically improves output performance as heat is removed directly from the active layer. The inventors have realised that there is great potential to utilise the presence of the heatspreader to perform a further selected optical function, such as cavity control, that may be used to advantage in a compact, high-power, vertically emitting laser source or amplifier. Also, by providing the heatspreader inside the optical cavity, the further selected effect may be on intracavity light; intracavity light is generally more significantly affected by changes in the device than is extracavity light.

The optically resonant cavity may be a Fabry-Perot cavity formed by the first and second mirrors. There may be more mirrors involved in forming the optically resonant cavity, for example it may be a three- or four-mirror cavity. In an example of a three-mirror cavity, the first mirror is arranged on the first side of the active layer and the second and third mirrors are arranged on the second, opposite side of the active layer, such that light passes from the second mirror to the third mirror via the first mirror and the chip, forming a v-shaped cavity with the chip at the point of the ‘V’.

The first or second mirror may be any suitable reflector, such as a plurality of semiconductor layers, a plurality of dielectric layers, a metal layer or merely an interface surface between two materials, such as an air-semiconductor interface at a surface of the chip.

The device may be a laser, such as a VCSEL or VECSEL, or an optical amplifier, such as a VCSOA or any other suitable device in which the resonant cavity passes through the active layer in a direction not in the plane of the active layer. The cavity may be substantially perpendicular to the active layer.

The selected property may be birefringence; thus, the heatspreader may be birefringent and the further selected effect may be on the polarisation of the output light. Many optically transparent materials suitable for use as the heatspreader exhibit birefringence. In a birefringent material, light of a first polarisation sees a different refractive index from light of a second, orthogonal polarisation. The strength of birefringence of a material is characterised by the difference An between the refractive indices of the material's slow and fast polarisation axes, Δn=nₛ−n_{f}. Thus, Δn may be greater than 0.01; in many applications, larger values of Δn are advantageous, for example Δn may be greater than a value x, where x=0.02, 0.05, 0.06, 0.07, 0.10, 0.15, 0.20, 0.30 or even 0.40.

Birefringence may be used to control the polarisation of the output from the device (vertically emitting lasers and optical amplifiers are theoretically unpolarised, neglecting other strain effects). Such polarisation control and selection of the output is well suited to many applications, including pumping arrangements in which the gain is polarisation-dependent in optical fibres, such as Raman-amplifier pumping. The device may comprise a further element that limits the device output light to a linear polarisation.

Alternatively, the selected property may be a property other than birefringence of the heatspreader.

The selected property may be a nonlinear optical response. The further selected effect may then be a nonlinear effect such as frequency doubling, frequency mixing or Kerr lensing. Such a nonlinear response will generally be a property of the material of which the heatspreader is made; many nonlinear materials are known in the art.

The heatspreader may act as a loss modulator, for example an electro-optic, acousto-optic or surface-acoustic-wave modulator. The further selected effect would then be a loss introduced into intracavity light. The loss may be periodic, for example to produce optical pulses. The loss may be used to encode information on the light, for example in a telecom laser.

The selected property may be the shape of the heatspreader; thus the shape of the heatspreader may provide the further selected effect. For example, the second surface of the heatspreader may be curved or may include a curved structure. The heatspreader may thus focus or defocus the output light. Advantageously, the heatspreader may focus pump light into the active layer.

The chip may comprise the second mirror. The second surface of the heatspreader may be curved. It may be used to focus pump light into the active layer or for collimating the signal output, or for both simultaneously.

The further selected effect may be on light generated in the active semiconductor layer at a fundamental frequency of the device. Alternatively, the effect may be on light generated at a new frequency in a non-linear element in the device, such as second-harmonic light. The heatspreader may itself be the nonlinear element and the further selected effect may be the generation of a new frequency.

The selected property of the heatspreader may have been selected to affect the spectrum of the output light. For example, a refractive index match or mismatch between the heatspreader and the chip may be used to tailor the output spectrum. The selected property may be a property other than a refractive-index mismatch between the heatspreader and the chip.

The heatspreader may have a refractive index that has been selected to provide substantially no refractive index step at the first surface. If the heatspreader and the chips are suitably index matched then the addition of the heatspreader effectively lengthens the optically resonant sub-cavity to incorporate the heatspreader. The resultant sub-cavity Fabry-Perot resonances will be more closely spaced for this greatly elongated sub-cavity; the output spectrum will then be linewidth-broadened and channelled.

Such a broadened and channelled output spectrum is well suited for example to the potential application of pumps for telecomm Raman amplifiers. For Raman amplifiers, performance is greatly increased by pumping over a broad region to flatten the gain at the signal wavelength (typically 1550 nm) and to promote the gain mechanism—stimulated Raman scattering (SRS)—while suppressing the major non-linear loss mechanism of stimulated Brillouin scattering (SBS). Although the SBS threshold (˜10 mW) is lower than the SRS threshold (˜1 W), SBS is confined to a relatively narrow bandwidth (typically ˜10 MHz) while SRS is a broad band effect extending up to ˜30 THz. SBS threshold is therefore dependent on power per unit frequency and SBS can be countered by spreading the pump power over a broader bandwidth; that effectively raises the SBS threshold well above that of SRS. In the prior art, the spreading of pump power is achieved by coupling a number of relatively narrow band, lower-power DFB lasers into the amplifier. The broader output of high-power VECSELs means that a small number or even a single pump laser can be used to directly drive the amplifier at powers below the SBS threshold but well above the overall SRS threshold.

The increased number of cavity or sub-cavity resonances within the mirror reflection band may also be advantageous for other applications, particularly because they may provide a choice of a larger number of potential pump wavelengths.

As is well known, the reflectivity R of an interface between two dielectric materials at normal incidence is given by:

$$R = {( \frac{{n}_{2} - {n}_{1}}{{n}_{2} + {n}_{1}} )}^{2} ,$$

where the light is incident on the material having index n₁ from the material having index n₂.

The maximum value of R that could be said to correspond to index matching varies between applications. Thus, the reflectance at the first surface may for example be less than a value y, where y=5%, 2%, 1%, 0.5%, 0.2% or even 0.1%.

Alternatively, the heatspreader may have a refractive index that has been selected to provide a refractive index step at the first surface. Thus the interface may provide an extra refractive index step between the heatspreader and the chip, which may be used to create an additional Fabry-Perot sub-cavity. (The sub-cavity would be additional to the usual VECSEL sub-cavity resulting from surface/air interface reflections).

The second surface of the heatspreader may be at an angle to the layers of the chip. Thus the second surface may be polished at an angle to form a wedge, which may provide sub-cavity suppression for an ‘antiresonant’ device, without the need for an anti-reflection (AR) coating.

The inventors have realised that the addition of the heatspreader also allows for spatial control of the cavity mode. Thus the heatspreader may have a shape selected to provide control of a spatial mode of the output light. For example, some curvature may be incorporated into the second surface of the heatspreader to promote mode stability and/or mode selection. The curved feature may be bonded intracavity and acts as an intra-cavity lens. The heatspreader may thus focus or defocus intracavity light. The heatspreader may be arranged to force lasing in a particular spatial mode output (for example in TEM00 only), for example for beam shape stability and coupling applications.

The second mirror may be flat. A prior-art VECSEL having a flat second mirror would in principle be unstable (although thermal lensing effects may provide stability in practice); however, the curved second surface may be arranged to enable a stable cavity mode to be formed. That has potential advantages for example when a Micro-electro-mechanical Systems (MEMS) mirror is used for fine tuning applications. Planar MEMS structures are much easier and cheaper to achieve than curved ones and moving the necessary curvature in the resonator geometry from the end mirror to the heatspreader is therefore advantageous. Thus the second mirror may be a MEMS mirror.

The second surface of the heatspreader may have a dielectric coating. The dielectric coating may be an anti-reflection coating. Such an AR coating could for example be used to tailor the output spectrum of the light, for example in conjunction with the refractive index step between the device and heatspreader.

Alternatively, the dielectric coating may be a mirror coating and form the second mirror. With suitable coatings, the second surface of the heatspreader may form the output coupler of a monolithic device, of the kind often referred to as a “microchip” laser or amplifier. The second surface of the heatspreader may be curved. Alternatively, there may be thermal lensing effects in the device that permit stable laser operation, even if the second surface of the heatspreader is planar and forms with the first mirror a two-mirror resonator cavity. Thus a microchip VECSEL may be provided, offering a stable mode output, which would advantageously be a compact and simple source for many applications.

The device may be a VCSEL and the heatspreader may act to reduce the reflectivity of the second mirror. That would raise the laser threshold but be beneficial for VCSOA operation of the device.

The heatspreader is preferably sufficiently thick (i.e. the distance between its first and second surfaces is sufficiently large) to provide good removal of heat from the active region. However, once sufficient heat removal is provided, it may be advantageous for the heatspreader to be thinner rather than thicker. Thus the heatspreader may have a thickness of less than a value z, where z=1.5 mm, 1 mm, 800 microns, 500 microns, 300 microns or even 100 microns.

In describing the first surface of the heatspreader as being ‘adjacent’ to the chip, we specify only that it is sufficiently close for the heatspreader to effectively remove heat. Thus, the first surface of the heatspreader may be separated from the chip by one or several layers of material suitably chosen (thin, highly conductive) so that the heat spreading function of the heatspreader is not impaired significantly.

Also according to the invention there is provided a method of manufacturing a vertical-cavity device, comprising:
(a) fabricating a chip comprising an active semiconductor layer for providing optical gain;
(b) providing a first mirror on a first side of the active layer;
(c) providing a second mirror on a second side of the active layer, opposite to the first mirror, which forms with at least the first mirror an optically resonant cavity that passes through the active layer in a direction out of the plane of the active layer;
(d) providing in the cavity a heatspreader for removing heat from the active layer, the heatspreader having a first surface adjacent to the chip and a second-surface opposite to the first surface, the heatspreader being transparent to light of wavelengths in the operating bandwidth of the device;
   characterised in that the method also includes the step of selecting one or more property of the heatspreader to have a selected effect on the output light, in addition to the effects of removing heat from the active layer.

The method may comprise the step of forming the first mirror by depositing a plurality of semiconductor layers on a substrate.

The heatspreader and the chip may be bonded together. The bonding may be by any suitable method, for example capillary bonding, wafer fusion bonding or mechanical bonding.

The method may include the step of forming the second surface of the heatspreader to be curved or to include a curved structure. The curved surface or the curved structure may be formed by polishing. The curved surface or the curved structure may be formed by etching. Thus surface features on the heatspreader may be achieved prior to bonding using any suitable method, for example, by bulk polishing or plasma etching of the heatspreader. The latter method may comprise resist coating the surface of the heatspreader and melting the resist to form a lens-like island which is then etched into the surface of the heatspreader.

Also according to the invention there is provided a device manufactured by a method described above as being according to the invention.

Also according to the invention there is provided an amplifier including a source of pump light comprising a device described above as being according to the invention.

The amplifier may be a Raman amplifier.

Also according to the invention there is provided a device comprising:
(a) a chip comprising an active semiconductor layer for providing optical gain,
(b) a first mirror on a first side of the active layer;
(c) a second mirror arranged on a second side of the active layer, opposite to the first mirror;
(d) a heatspreader for removing heat from the active layer, the heatspreader having a first surface adjacent to the chip and a second surface opposite to the first surface, the heatspreader being transparent to light of wavelengths in the operating bandwidth of the device;
   wherein output light generated in the active layer passes through the heatspreader and is emitted through the second mirror.

The heatspreader may be birefringent. The heatspreader may comprise a further element that limits the output to a linear polarisation.

The second surface of the heatspreader may be not parallel to its first surface.

The second surface of the heatspreader may be curved or include a curved structure.

Also according to the invention there is provided a vertical cavity device comprising:
(a) a chip comprising an active semiconductor layer for providing optical gain;
(b) a first mirror arranged on a first side of the active layer suitable for forming with at least a second mirror arranged on a second side of the active layer, opposite to the first mirror, an optically resonant cavity that passes through the active layer in a direction out of the plane of the active layer; and
(c) a heatspreader for removing heat from the active layer, having a first surface adjacent to the active layer and a second surface opposite to the first surface, the heatspreader being transparent to light of wavelengths in an operating bandwidth of the device;
   characterised in that, in addition to removing heat from the active layer, the heatspreader also has one or more further selected property that has a further selected effect on light output from the device.

Illustrative embodiments of the invention will now be described in detail, by way of example only, with reference to the accompanying drawings in which:

FIG. 1 is a schematic of (a) a prior art VECSEL structure and (b) a prior art VCSEL structure;

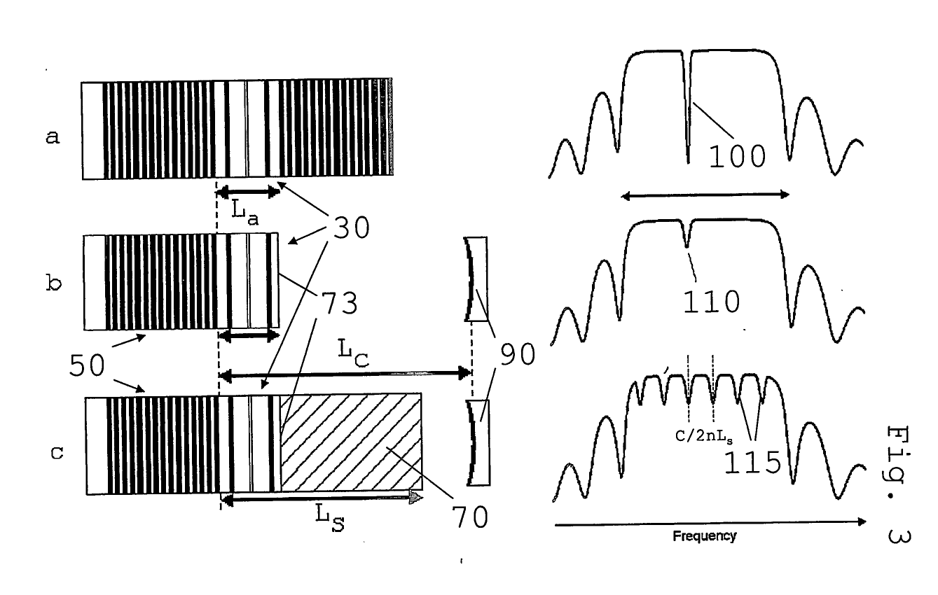

FIG. 2 is the device of FIG. 1(a) including a heatspreader;

FIG. 3 is a device structure and a reflectivity spectrum for light output from the device, in the cases of (a) a prior-art VCSEL, (b) a prior-art VECSEL and (c) a device according to the invention;

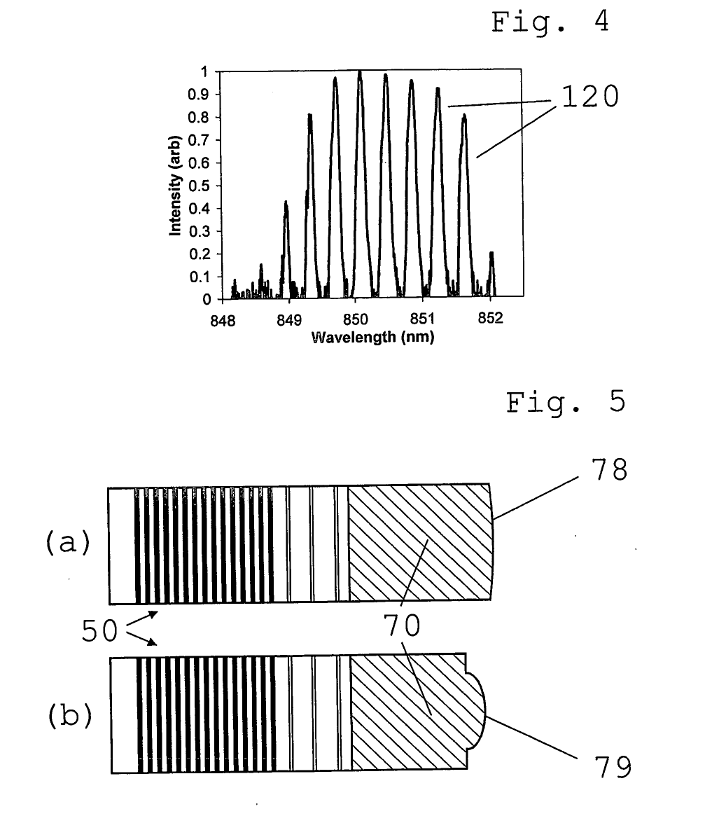

FIG. 4 is an experimentally recorded spectral output of a device according to the invention;

FIG. 5 is a schematic of two further device structures according to the invention;

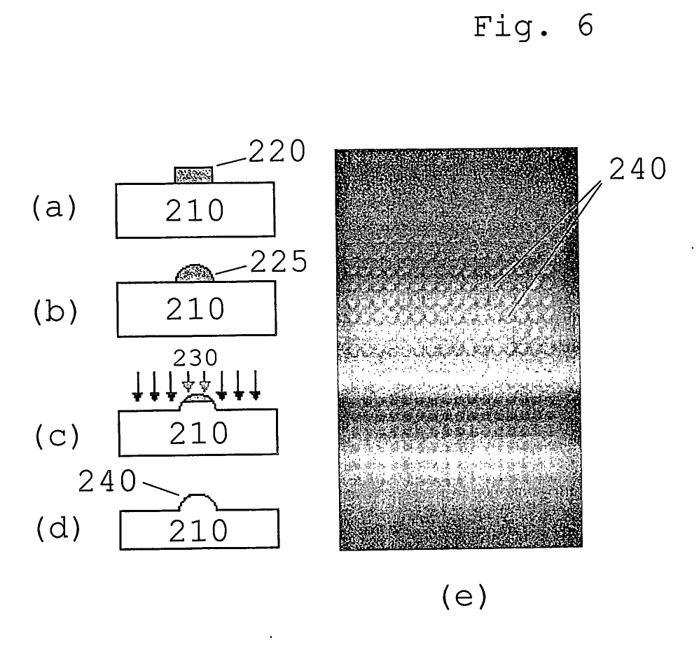

FIG. 6 is (a) a schematic of steps in etching of a microlens in a heatspreader in a device according to the invention and (b) an optical micrograph of an array of lenses etched in this way in sapphire;

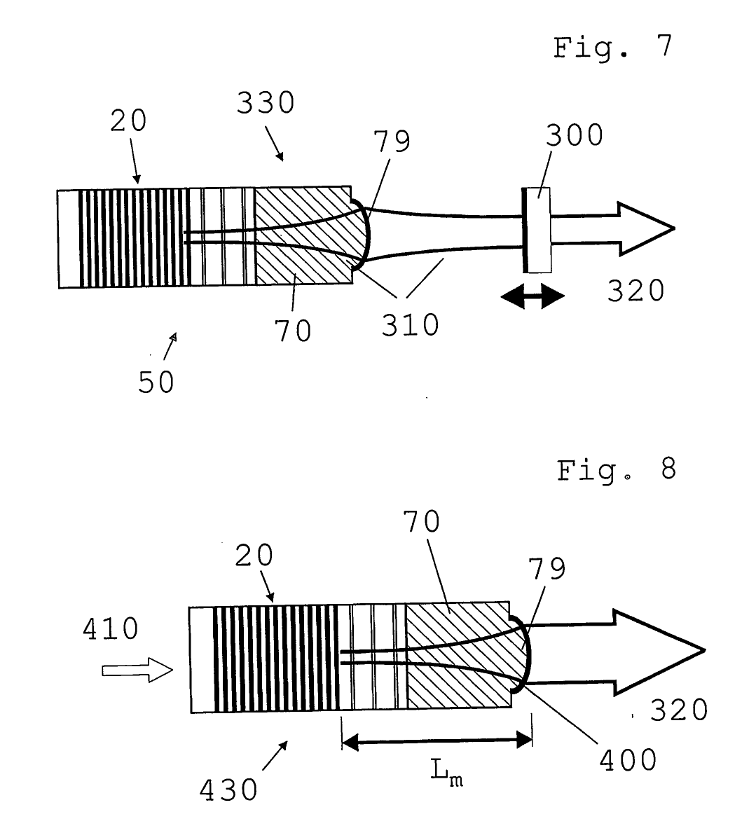

FIG. 7 is another example of a device according to the invention;

FIG. 8 is another example of a device according to the invention.

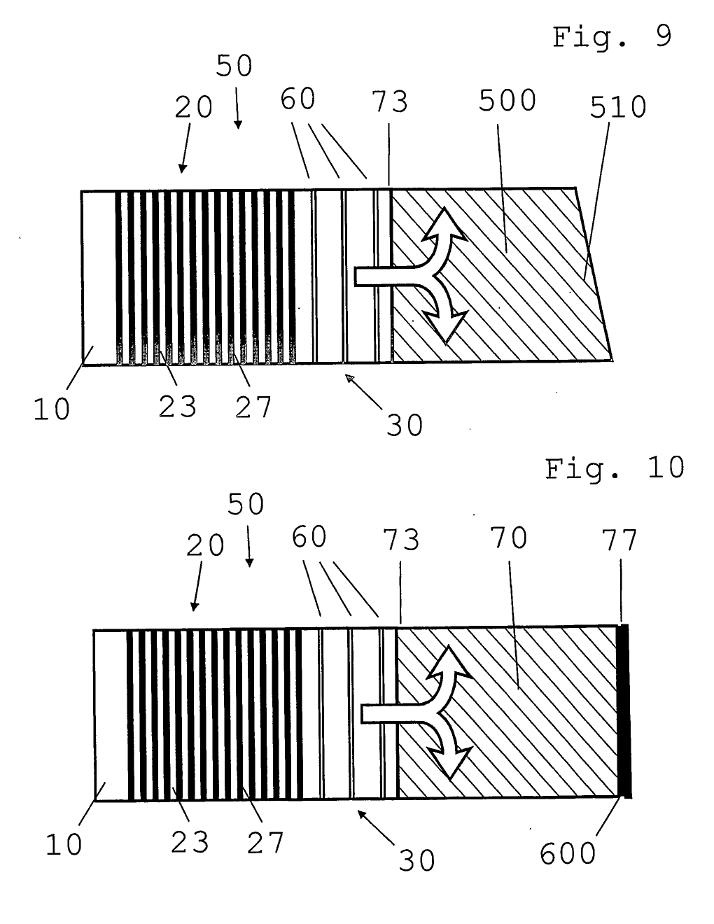

FIG. 9 is another example of a device according to the invention.

FIG. 10 is an example of a monolithic device according to the invention.

The prior art structures of FIG. 1 have been discussed above.

A laser element (FIG. 2) comprises a chip 50. The chip includes a substrate 10, a mirror 20 and an active semiconductor layer 30. The mirror 20 is a DBR formed of a plurality of layers 23, 27, with alternate layers 23, 27 being of semiconductor material having a higher and a lower refractive index respectively. Active layer 30 includes six quantum wells 60, which provide optical gain, arranged at positions co-incident with antinodes of the laser signal field (resonant periodic gain).

The element also comprises an optically flat (polished) optically transparent substrate in the form of a heatspreader 70, which removes heat directly from the gain region, active layer 30, to improve output power and/or performance. The heatspreader 70 is bonded to chip 50 at interface surface 73. The heatspreader also has external surface 77.

Typically the heatspreader dimensions (specifically length along the emission axis) will be much greater (˜100 s microns) than the semiconductor cavity thickness of the chip (˜microns).

The heatspreader 70 is in good thermal contact with a heatsink (not shown). The path of heat from the active region 30 to the heatsink is shown schematically by the broad arrows in FIG. 2.

In the manufacture of the device of FIG. 2, chip 50 is bonded to heatspreader 70 via liquid capillary bonding. A liquid (usually methanol or water) is placed between the semiconductor chip 50 and the heatspreader 70. Mechanical pressure is then applied and the liquid is allowed to evaporate resulting in a Van-der-Walls bond between the two surfaces.

The primary function of the arrangement is to remove heat directly from the ‘pumped’ active region 30 of the device to improve high-power performance. The reduction in temperature rise of the active region 30 due to this increased heat extraction results in the device performing more efficiently at higher pump energies due to a reduction in both parasitic non-radiative effects and thermal walk off of the physical structure (RPG and peak emission) from the optimum operating conditions.

The fact that the heatspreader 70 is distinct from and is subsequently bonded to the semiconductor device 50 means that there is the possibility of choosing the mechanical and optical properties of the heatspreader 70 and/or performing particular processing steps before bonding to allow the heatspreader to perform a second optical function.

As is well known, a pair of partially reflecting surfaces separated by physical distance L exhibit transmissivity peaks having a separation in frequency of c/2nL, where c is the speed of light and n is the refractive index of the material between the surfaces (2nL is thus the round-trip optical path length between the surfaces). A laser incorporating such a pair of surfaces (a Fabry-Perot cavity) will only operate at the frequencies of those peaks, which are called the longitudinal modes of the cavity. Furthermore, the gain and loss spectra of the laser limit laser action to those longitudinal modes for which gain exceeds loss.

The reflectivity profile of a VCSEL (FIG. 3(a)) shows a deep trough 100 near the middle of a broad band of frequencies (double-headed arrow) at which the cavity is otherwise relatively highly reflecting. That deep trough 100 determines the frequency at which the laser oscillates. Only one trough appears in that part of the reflectivity spectrum because the longitudinal mode separation c/2nlₐ (where lₐ is the width of the active region) is much larger than the width of the plateau of high reflectivity.

A VECSEL (FIG. 3(b)) does not have the second mirror 40 of a VCSEL; rather, it has curved external mirror 90. However, a trough 110 still appears at the same place in the reflectivity spectrum as in the reflectivity spectrum of the corresponding VCSEL structure. Trough 110 results from a resonance in the active region 30 of the chip 50, resulting from reflections between the first mirror 20 and the surface 73 of the chip 50. The separation of the mirrors 20, 73 forming that subcavity is the same as in the VCSEL case (mirrors 20, 40) and so the subcavity resonance occurs at the same frequency, c/2nlₐ. Of course, the presence of the external mirror will result in a comb of closely spaced resonances (frequency spacing c/2nl_{c}) superimposed on the chip reflectivity spectrum (those resonances are not shown in FIG. 3(b))

In a VECSEL that is an embodiment of the invention (FIG. 3(c)), chip 50 and heatspreader 70 are refractive index-matched at surface 73. (Heatspreader 70 is of silicon-carbide, SiC (n˜2.6), chip 50 is a GaAs (n˜3)-based device; the refractive indices are thus quite closely matched.) Consequently, there are no subcavity resonances caused by reflections between mirror 50 and surface 73. Rather, a subcavity is formed between mirror 50 and the external surface 77 of heatspreader 70. This subcavity has a physical length Lₛ, that is longer than Lₐ, and its optical length nLₛ is longer still. Consequently, this device exhibits subcavity resonances at a frequency spacing c/2nLₛ, which is significantly smaller than c/2nlₐ (and usually significantly smaller than c/2nl_{c}). The resonance spacing is sufficiently small for multiple troughs 115 to appear within the high-reflection plateau.

The output spectrum recorded from a device having the form of the VECSEL of FIG. 3(c) exhibits, as expected, a plurality of peaks 120 (FIG. 4) corresponding to the troughs 115 of FIG. 3(c), that is the longitudinal modes of the subcavity. Seven high-intensity modes can be identified in FIG. 4, separated by approximately 0.4 nm. Two smaller modes can be seen on either side of those seven, with traces of two more also visible on the low wavelength side of the recorded spectrum.

The inventors have realised that the extra material ‘real-estate’ offered by the addition of a heatspreader may be processed in some way prior to bonding.

A particular advantage is obtained when heatspreader 70 is provided with a curved external surface (FIG. 5). In FIG. 5 (a), heatspreader 70 has an external surface 78 that exhibits a slight convex curvature. The curvature is achieved by polishing.

In FIG. 5(b), a convex curvature is provided in the form of a curved external surface region 79, which is achieved by etching.

In an example of the etching process (FIG. 6(a)-(d)), substrate 210 is first coated with resist 220 in the region at which the lens is to be formed (FIG. 6(a)). The resist is melted to form a hemispherical lens-like island of resist 225 (FIG. 6(b)). The surface of substrate 210 is exposed to a plasma (FIG. 6(c)), which etches substrate 210 and resist 225 to form hemispherical region 240 (FIG. 6(d)). FIG. 6(e) shows an array of lenses 240 that have been etched by the inventors for the first time to our knowledge into sapphire using this method (we have also achieved etching of such lenses in Silicon Carbide). This etching method is most suited to the formation of micro-structures on the order of up to 10's microns.

Thus heatspreader 70 may readily be provided with a curved outer surface 78, 79. Such a surface acts as a convex lens on light emitted from active region 30. In a standard VECSEL, mirror 90 is curved to provide a stable laser resonator (a simple Fabry-Perot cavity comprising two planar surfaces is only just stable in theory and is in practice unstable in the extended cavity of a VECSEL). A particular advantage of providing a convex curved surface 78, 79 on heatspreader 70 is that stable laser operation can then be achieved using a planar end mirror 300 (FIG. 7). In the arrangement of FIG. 7, VECSEL 330 comprises a optically resonant cavity comprising a first mirror in the form of DBR 20, an output coupler in the form of planar mirror 300 and the heat-spreader having lens-like curved surface 79 (the interface between chip 50 and heatspreader 70 is again index-matched). In a round-trip of the cavity, intracavity mode 310 makes two passes through lens 79. It is focused by lens 79 onto output-coupler 300, from which collimated beam 320 emerges. In addition to provision of a collimated output, another advantage of achieving laser operation with a planar end mirror is that the laser may readily be tuned by moving the end mirror to alter the length of the laser cavity (and hence the frequency of the longitudinal cavity modes).

Another example of a novel VECSEL structure enabled by provision of a curved surface on heatspreader 70 is shown in FIG. 8. Laser 430 is a monolithic structure in which an output couple is provided at the curved surface 79 of the heatspreader by providing a dielectric coating of high reflectivity directly onto that surface. A (stable) laser resonator cavity is thus formed between DBR 20 and coating 400 on surface 79. The cavity has a length Lₘ that is significantly longer than the length Lₐ of active region 30 and the advantages discussed above of the longer cavity length, such as lasing on a plurality of longitudinal modes, are again provided. However, laser 430 has the further advantage that, being monolithic, it provides the simplicity and stability of a standard VCSEL structure but retains the advantages of extended cavity configurations.

The device 430 is optically pumped with a pump beam 410 from a diode laser array (not shown). It will readily be understood by the skilled person that this and other embodiments of the invention may be pumped by any suitable pumping scheme, including optical or electrical pumping schemes; examples of such schemes are well known in the prior art.

In some applications, it will be advantageous to provide further sub-cavity resonances. That is achieved by providing a refractive-index mismatch at surface 73 of heatspreader 70 adjacent to chip 50. Subcavity resonances would then result from reflections in active region 30 and heatspreader 70 (at DBR 20, surface 73, surface 77 and external mirror 90).

In some applications, it will be advantageous to reduce or substantially eliminate sub-cavity resonances. As discussed above, index-matching at the first surface 73 of the heatspreader 70 reduces or eliminates reflections from that surface. Two arrangements for eliminating or reducing resonant reflections from the second, opposite surface 77 of the heatspreader 70 are shown in FIGS. 9 and 10.

One approach (FIG. 9) is to provide heatspreader 500 with a second surface 510 at an angle to its first surface 73 (and hence to the layers of the chip 50). Heatspreader 500 thus has a truncated wedge-shape. Reflections from surface 500 are thus reflected out of the cavity, rather than towards mirror 20, and so resonant reflections do not build up.

Another approach (FIG. 10) is to provide plane-parallel heatspreader 70 with an anti-reflection dielectric coating 600 at its surface 77. Anti-reflection coatings are themselves Fabry-Perot stacks and are least reflective over a relatively narrow range of wavelengths. Anti-reflection coatings are readily engineered to provide a desired reflectivity profile, in particular to provide low reflectivity at specific wavelengths. The reflectivity profile of coating 600 is chosen to provide laser output having a desired spectral profile.

In another embodiment, chip 50 and heatspreader 70 of the device shown in FIG. 10 are not index-matched, so reflections occur at surface 73. The AR coating 600 is again engineered to select particular longitudinal cavity modes and thus tailor spectral output.

In another embodiment, AR coating 600 on heatspreader 70 in the embodiment of FIG. 10 is replaced by a coating that is highly reflecting (HR) at the signal wavelength. A resonator cavity is thereby formed between mirror 20 and the HR coating on the heatspreader. Although such a resonator cavity might be expected to be on the edge of instability (as it is a cavity formed from two planar mirrors), in practice thermal lensing effects in the device permit stable operation.

For some applications, it is desirable for the laser to provide polarised light. In some embodiments of the invention, heatspreader 70 is made from material that is birefringent. Light generated from such a laser will generally be polarised. The light will generally be elliptically polarised; plane polarised light may readily be provided by careful selection of the thickness of the heatspreader 70 or by provision of appropriate intracavity or extracavity polarisation filters.

In an alternative embodiment, the pump and signal are co-linear and are coupled to the device via a dichroic mirror.

Other embodiments and variations of the invention will be readily apparent to the person skilled in the art.

1. A vertical-cavity device comprising:
(a) a chip comprising an active semiconductor layer for providing configured to provide optical gain;
(b) a first mirror arranged on a first side of the active layer;
(c) a second mirror arranged on a second side of the active layer, opposite to the first mirror, and forming with at least the first mirror an optically resonant cavity that passes through the active layer in a direction out of the plane of the active layer; and
(d) a heatspreader for removing heat from the active layer, the heatspreader being arranged inside the cavity and having a first surface adjacent to the chip and a second surface opposite to the first surface, the heatspreader being transparent to light of wavelengths in an operating bandwidth of the device and having at least one selected property that has a further selected effect on light output from the device.

2. A device as claimed in claim 1, in which the heatspreader is birefringent and the further selected effect is on the polarisation of the output light.

3. A device as claimed in claim 2, in which the difference in between the refractive indices of the heatspreader's slow and fast polarisation axes is greater than 0.01.

4. A device as claimed in claim 2, comprising a further element that limits the output light to a linear polarisation.

5. A device as claimed in claim 1, in which the heatspreader has a nonlinear optical response.

6. A device as claimed in claim 1, in which the shape of the heatspreader provides the further selected effect.

7. A device as claimed in claim 6, in which the second surface of the heatspreader is curved or includes a curved structure.

8. A device as claimed in claim 1, in which the heatspreader focuses or defocuses the output light.

9. A device as claimed in claim 1, in which the heatspreader focuses pump light into the active layer.

10. A device as claimed in claim 1, in which the further selected effect is on light generated in the active semiconductor layer at a fundamental frequency of the device.

11. A device as claimed in claim 1, in which the selected property of the heatspreader has been selected to affect the spectrum of the output light.

12. A device as claimed in claim 11, in which the heatspreader has a refractive index that has been selected to provide substantially no refractive index step at the first surface.

13. A device as claimed in claim 12, in which reflectance at the first surface of the heatspreader is less than 5%.

14. A device as claimed in claim 10, in which the heatspreader has a refractive index that has been selected to provide a refractive index step at the first surface.

15. A device as claimed in claim 1, in which the second surface of the heatspreader is at an angle to the layers of the chip.

16. A device as claimed in claim 1, in which the heatspreader has a shape selected to provide control of a spatial mode of the output light.

17. A device as claimed in claim 16, in which the heatspreader focuses or defocuses intracavity light.

18. A device as claimed in claim 17, in which the second mirror is flat.

19. A device as claimed in claim 18 in which the second mirror is a MEMS mirror.

20. A device as claimed in claim 1, in which the second surface of the heatspreader has a dielectric coating.

21. A device as claimed in claim 20, in which the dielectric coating is an anti-reflection coating.

22. A device as claimed in claim 20, in which the dielectric coating is a mirror coating and forms the second mirror.

23. A device as claimed in claim 1, in which the heatspreader has a thickness of less than 1.5 mm.

24. A device as claimed in claim 1, in which the heatspreader is a loss modulator.

25. A method of manufacturing a vertical-cavity device, comprising:
(a) fabricating a chip comprising an active semiconductor layer for providing optical gain;
(b) providing a first mirror on a first side of the active layer;
(c) providing a second mirror on a second side of the active layer, opposite to the first mirror, which forms with at least the first mirror an optically resonant cavity that passes through the active layer in a direction out of the plane of the active layer;
(d) providing in the cavity a heatspreader for removing heat from the active layer, the heatspreader having a first surface adjacent to the chip and a second surface opposite to the first surface, the heatspreader being transparent to light of wavelengths in the operating bandwidth of the device; and
(e) selecting at least one property of the heatspreader to have a selected effect on the output light, in addition to the effect of removing heat from the active layer.

26. A method as claimed in claim 25, including the step of forming the second surface of the heatspreader to be curved or to include a curved structure.

27. A method as claimed in claim 26, in which the curved surface is formed by polishing.

28. A method as claimed in claim 26, in which the curved surface or the curved structure is formed by etching.

29. A device manufactured by a method according to claim 25.

30. An amplifier or laser including a source of pump light comprising a device according to claim 1.

31. An amplifier or laser as claimed in claim 30 that is a Raman amplifier.

32. A vertical cavity device comprising:
(a) a chip comprising an active semiconductor layer for providing optical gain;
(b) a first mirror arranged on a first side of the active layer suitable for forming with at least a second mirror arranged on a second side of the active layer, opposite to the first mirror, an optically resonant cavity that passes through the active layer in a direction out of the plane of the active layer; and
(c) a heatspreader for removing heat from the active layer, having a first surface adjacent to the active layer and a second surface opposite to the first surface, the heatspreader being transparent to light of wavelengths in an operating bandwidth of the device and,
in addition to removing heat from the active layer, at least one further selected property that has a further selected effect on light output from the device.
